(19) United States
(12) Patent Application Publication
(10) Pub. No.: US 2012/0012943 A1
(43) Pub. Date: Jan. 19, 2012

(54) ANTI-FUSE OF SEMICONDUCTOR DEVICE AND METHOD OF MANUFACTURING THE SAME

(75) Inventor: Yong Sun JUNG, Icheon (KR)

(73) Assignee: Hynix Semiconductor Inc., Icheon (KR)

(21) Appl. No.: 13/181,472

(22) Filed: Jul. 12, 2011

(30) Foreign Application Priority Data
Jul. 13, 2010 (KR) 10-2010-0067321

(51) Int. Cl. H01L 27/06; H01L 21/8234

(52) U.S. Cl. 257/379; 438/238; 257/E27.014; 257/E21.616

(57) ABSTRACT

The present invention provides an anti-fuse of a semiconductor device and a method of manufacturing the same, which has a stable current level and a stable operation. According to the present invention, in order for the anti-fuse to be stably operated, a region in which a gate and an active region partially overlap with each other is formed, and the overlapped region is destroyed when voltage is supplied. Accordingly, a current level can be stabilized, and stable operation is possible.

### CROSS-REFERENCE TO RELATED APPLICATION

Priority to Korean patent application number 10-2010-0067321, filed on Jul. 13, 2010, which is incorporated by reference in its entirety, is claimed.

### BACKGROUND OF THE INVENTION

The present invention relates to an anti-fuse of a semiconductor device and a method of manufacturing the same.

With the recent rapid spread of information media, such as computers, advancements in semiconductor devices are making rapid progress. In terms of function, semiconductor devices require high-speed operation and high-capacity storage capability. Semiconductor devices are being developed in order to improve degree of integration, reliability, response speed, etc.

Semiconductor devices are chiefly fabricated by a fabrication (FAB) process, which forms cells having integrated circuits by repeatedly forming defined circuit patterns on a substrate made of silicon, and an assembly process of packaging the substrate having the cells formed thereon on a chip basis. An electrical die sorting (EDS) process of testing the electrical properties of the cells formed on the substrate is further performed between the fabrication process and the assembly process.

This test process is performed to determine whether the cells formed on the substrate have a good or poor electrical state. Efforts and costs consumed in the assembly process can be reduced by performing the test process before the assembly process to eliminate defective cells . Furthermore, if the defective cells are detected in early stages, they can be repaired through a repair process.

The conventional repair process is described in detail below.

In order to improve the production yield of semiconductor devices, redundant cells are added when the devices are designed in order to replace defective elements and circuits, with the redundant cells. Fuses are also designed in order to couple the redundant cells to the integrated circuits. The repair process is performed to repair a cell, determined to be defective through the test process, by coupling the defective cell to the redundant cell using the fuse. That is, positional information about cells to be repaired is generated by cutting specific fuses.

However, although this repair process is performed and removes defects at the wafer level, defects of 1 bit or 2 bits are generated in chips after the package process is performed. Usually, about 10% of devices are turned out to be defective after packaging. Accordingly, a repair process should be performed after the package process. In particular, when a multi-chip package (MCP) has some defective cells in DRAM, or in relatively expensive flash RAM, it should be thrown away. Accordingly, the introduction of the repair process after the package process is indispensable.

A post package repair process must be different from the pre-package repair process because laser repair equipment for a pre-package repair process cannot be used for a post package repair process. A fuse used in a repair process performed after the package process is described below.

A fuse used for a post package repair process is usually called an anti-fuse. This is because a pre-package repair process is performed by cutting a fuse, whereas a post package repair process is performed by interconnecting a fuse. That is, the name “anti-fuse” originated from its functional configuration, which is opposite to a fuse used for a pre-package repair process. The anti-fuse is electrically isolated in a normal state, but is an electrically shorted state when an insulating material between conductive materials is cut so that high voltage is supplied to the anti-fuse. The anti-fuse is formed in a periphery region. Redundant cells for the anti-fuse are also formed in the periphery region, but are formed of SRAM cells that do not require a refresh operation.

FIG. 1 is a plan view illustrating a conventional anti-fuse.

Referring to FIG. 1, isolation layers 120 defining an active region 110 are formed over a semiconductor substrate 100. Source/drain regions 130 are formed in the active region 110. The source/drain regions 130 are formed by implanting N type impurity ions.

A gate pattern 160 is provided over the active region 110. First metal contacts 170 are coupled to the gate pattern 160, and second metal contacts 170′ are coupled to the source/drain regions 130 and the active region 110. Here, a gate oxide layer (not shown) under the gate pattern 160 is destroyed when different voltages are supplied to the first and the second metal contacts 170 and 170′.

When a voltage is supplied through the first and the second metal contacts 170 and 170′, a fuse coupled to the entire region A of the active region 110 that overlaps with the gate pattern 160 is destroyed, so that a current level of gate pattern 160 changed. The changed current level hinders the anti-fuse from stably operating.

FIG. 2 is a cross-sectional view illustrating the conventional anti-fuse of a semiconductor device of FIG. 1.

Referring to FIG. 2, the isolation layers 120 defining the active region 110 are formed over the semiconductor substrate 100. The active region 110 is formed by implanting P type impurity ions. The active region 110 is defined as a body portion.

Next, the source/drain regions 130 are formed by implanting impurity ions into the active region 110. The source/drain regions 130 are formed by implanting N type impurity ions. Next, a gate oxide layer 140 and a gate electrode layer 150 are sequentially formed over the active region 110. The gate electrode layer 150 is formed by implanting N type impurity ions.

After a photoresist layer (not shown) is formed on the gate electrode layer 150, a photoresist pattern (not shown) is formed by exposure and development processes using a mask defining the gate pattern. The gate electrode layer 150 and the gate oxide layer 140 are etched by using the photoresist pattern as an etch mask, thereby forming the gate pattern 160. The metal contacts 170 and 170′ coupled to the source/drain region 130, and the gate pattern 160 and the active region 110 are formed. Each of the metal contacts 170 and 170′ is formed of a tungsten (W) layer, a titanium (Ti) layer, a titanium nitride (TiN) layer or a combination thereof. Different voltages are supplied through the metal contacts 170 and 170′. The gate oxide layer 140 is destroyed when different voltages are applied between the metal contacts 170 and 170′, thus playing the role of an anti-fuse.

The fuse is destroyed over the entire region A of the active region 110, which overlaps with the gate pattern 160. Accordingly, current level is changed and the anti-fuse cannot be stably operated.

### BRIEF SUMMARY OF THE INVENTION

The present invention provides an anti-fuse of a semiconductor device, including isolation layers formed to define an isolation region over a semiconductor substrate, a junction provided over the active region, a gate pattern provided over the semiconductor substrate and formed to overlap with only part of the active region, first contact plugs coupled to the gate pattern, and second contact plugs coupled to the active region and the junction.

Preferably, the gate pattern includes a structure of a gate oxide layer and a gate electrode layer.

Preferably, each of the first and the second contact plugs is formed of a tungsten (W) layer, a titanium (Ti) layer, a titanium nitride (TiN) layer, or a combination thereof.

Preferably, the active region overlaps with the corner of an end of the gate pattern.

Furthermore, the present invention provides a method of manufacturing an anti-fuse of a semiconductor device, including forming isolation layers, defining an active region over a semiconductor substrate, forming a junction over the active region, forming a gate pattern that overlaps with only part of the active region over the semiconductor substrate, forming first contact plugs coupled to the gate pattern, and forming contact plugs coupled to the active region and the junction.

Preferably, the active region is formed by implanting P type impurity ions.

Preferably, forming the junction includes implanting N type impurity ions into the active region.

Preferably, forming the gate pattern includes sequentially forming a gate oxide layer and a gate electrode layer over the semiconductor substrate and etching the gate electrode layer and the gate oxide layer by using a gate mask as an etch mask until part of the active region is exposed.

Preferably, the gate electrode layer is formed by implanting N type impurity ions.

Preferably, the gate electrode layer includes a polymer layer, a tungsten (W) layer, a titanium (Ti) layer, a tungsten nitride (WN) layer, or a combination thereof.

Preferably, part of the gate oxide layer overlapping with the active region is destroyed.

Preferably, each of the first and the second contact plugs includes a tungsten (W) layer, a titanium (Ti) layer, a titanium nitride (TiN) layer, or a combination thereof.

### BRIEF DESCRIPTION OF THE DRAWINGS

FIG. 1 is a plan view illustrating a conventional anti-fuse of a semiconductor device;

FIG. 2 is a cross-sectional view illustrating the anti-fuse of FIG. 1;

FIG. 3 is a plan view illustrating an anti-fuse of a semiconductor device and a method of manufacturing the same according to an embodiment of the present invention; and

FIG. 4 is a cross-sectional view illustrating the anti-fuse of a semiconductor device of FIG. 3.

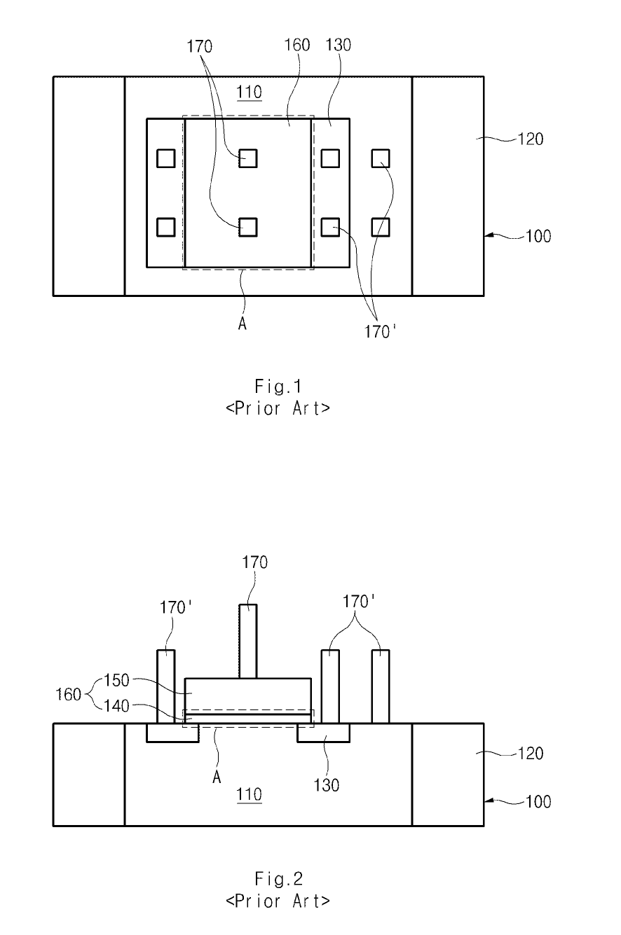

### DESCRIPTION OF EMBODIMENTS

Some exemplary embodiments of this disclosure will now be described in detail with reference to the accompanying drawings.

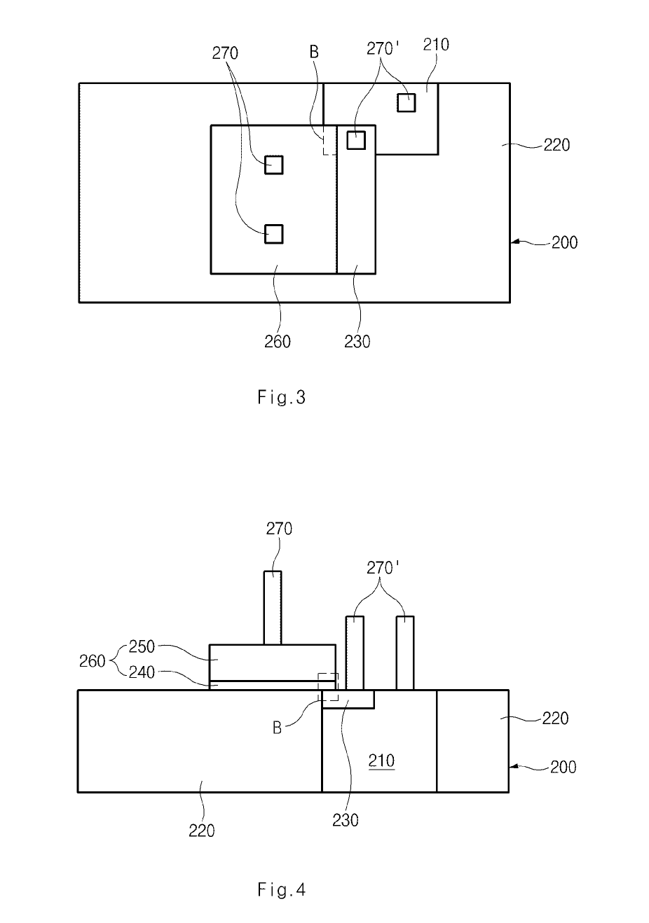

FIG. 3 is a plan view illustrating the anti-fuse of a semiconductor device and a method of manufacturing the same according to an embodiment of the present invention.

Referring to FIG. 3, isolation layers 220 defining an active region 210 are formed over a semiconductor substrate 200. Source/drain regions 230 and a junction are formed in the active region 210. The source/drain regions 230 partially overlap (B region) with a gate pattern 260, which is formed in a subsequent process. The source/drain regions 230 are formed by implanting N type or P type impurity ions.

The gate pattern 260 is provided over the isolation layers 220. First metal contacts 270 are coupled to the gate pattern 260, and second metal contacts 270′ are coupled to the source/drain regions 230 and the active region 210. A gate oxide layer (not shown) deposited under the gate pattern 260 is destroyed when different voltages are supplied to the first and the second metal contacts 270 and 270′, so that the gate oxide layer serves as an anti-fuse. The gate pattern 260 and the active region 210 partially overlap with each other, and only some regions (B region of the gate pattern 260, for example) are damaged when different voltages are supplied to the first and the second metal contacts 270 and 270′. Accordingly, a difference between current levels can be minimized, and the anti-fuse can be stably operated.

FIG. 4 is a cross-sectional view illustrating the anti-fuse of a semiconductor device according to an embodiment of the present invention.

Referring to FIG. 4, the isolation layers 220 defining the active region 210 are formed over the semiconductor substrate 200. It is preferred that the active region 210 is formed by implanting P type impurity ions. The active region 210 is defined as a body portion. The isolation layer 220 is formed such that the gate pattern 260, which is formed in a subsequent process, partially overlaps with the active region 210.

Next, the source/drain regions 230 are formed by implanting impurity ions into the active region 210. It is preferred that the source/drain regions 230 are formed by implanting N type impurity ions. The fuse is destroyed only in a region that overlaps with the active region 210 when a voltage is supplied to the fuse in a subsequent process. Accordingly, current levels can be reduced, and the anti-fuse can be stably operated.

Next, a gate oxide layer 240 and a gate electrode layer 250 are sequentially formed over the active region 210 and the isolation layers 220. It is preferred that N type impurity ions are further implanted into the gate electrode layer 250.

After a photoresist layer (not shown) is formed on the gate electrode layer 250, a photoresist pattern (not shown) is formed by exposure and development processes using an exposure mask defining a gate pattern. The gate electrode layer 250 and the gate oxide layer 240 are etched by using the photoresist pattern as an etch mask, thereby forming the gate pattern 260. Here, the gate pattern 260 serves as an anti-fuse and preferably partially overlaps with the active region 210. In an embodiment, it is preferred that a corner of an end of the gate pattern 260 overlaps with the active region 210 in order to minimize the region in which the active region 210 overlaps with the gate pattern 260.

Next, the first metal contacts 270, coupled to the gate pattern 260, and the second metal contacts 270′, coupled to the active region 210 and the source/drain regions 230, are formed. It is preferred that the first and the second metal contacts 270 and 270′ are formed of a tungsten (W) layer, a titanium (Ti) layer, a titanium nitride (TiN) layer or a combination thereof. The fuse is destroyed in a part of the active region 210 that overlaps with the gate pattern 260 when voltages are supplied through the first and the second metal contacts 270 and 270′. Accordingly, a difference between the current levels can be reduced, and the anti-fuse can be stably operated.

As described above, according to the present invention, in order for an anti-fuse to be stably operated, the gate and the active region partially overlap with each other, and a fuse formed in the overlapping region is destroyed when a voltage is supplied thereto. Accordingly, the anti-fuse can maintain a stable current level and operate reliably.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. An anti-fuse of a semiconductor device comprising:
an isolation layer defining an isolation region over a semiconductor substrate;
a junction disposed in an active region;
a gate pattern disposed over the semiconductor substrate and formed to partially overlap with the active region;
a first contact plug coupled to the gate pattern; and
a second contact plug coupled to the active region and the junction.

2. The anti-fuse according to claim 1, wherein the gate pattern includes a stack structure of a gate oxide layer and a gate electrode layer.

3. The anti-fuse according to claim 1, wherein each of the first and the second contact plugs is formed of a tungsten (W) layer, a titanium (Ti) layer, a titanium nitride (TiN) layer or a combination thereof.

4. The anti-fuse according to claim 1, wherein the active region overlaps with a corner of the gate pattern.

5. An anti-fuse for a semiconductor device comprising:
a gate patternformed in a device isolation region of a substrate and extending to an active region of the substrate;
a junction formed in the active region;
a first anti-fuse configured to insulate the gate pattern from the active region in a normal state, and further configured to couple the gate pattern to the active region in a repair state; and
a second anti-fuse configured to insulate the gate pattern from the junction in the normal state, and further configured to couple the gate pattern to the junction in the repair state.

6. The anti-fuse for a semiconductor device of claim 5, wherein the first anti-fuse is between the gate pattern and the substrate in the active region.

7. The anti-fuse for a semiconductor device of claim 6, wherein the first anti-fuse extends to the device isolation region.

8. The anti-fuse for a semiconductor device of claim 5, wherein the second anti-fuse is between the gate pattern and the junction.

9. The anti-fuse for a semiconductor device of claim 8, wherein the junction extends to the device isolation region.

10. The anti-fuse for a semiconductor device of claim 9, wherein the second anti-fuse extends to the device isolation region along the junction.

11. The anti-fuse for a semiconductor device of claim 5, wherein an area of the gate pattern formed in the device isolation region is larger than an area of the gate pattern formed in the active region of the substrate.

12. The anti-fuse for a semiconductor device of claim 5, wherein the first and the second anti-fuses are integrated into one body.

13. The anti-fuse for a semiconductor device of claim 12, wherein the integrated first and the second anti-fuses is a gate oxide layer for the gate pattern.

14. The anti-fuse for a semiconductor device of claim 5, wherein, in the repair state, the first anti-fuse is destroyed to couple the gate pattern to the active region, and
wherein, in the repair state, the second anti-fuse is destroyed to couple the gate pattern to the junction.

15. A method of manufacturing an anti-fuse of a semiconductor device, the method comprising:
forming an isolation layer defining an active region over a semiconductor substrate;
forming a junction over the active region;
forming a gate pattern over the semiconductor substrate to be partially overlapping with the active region;
forming a first contact plug coupled to the gate pattern; and
forming a second contact plug coupled to the active region and the junction.

16. The method according to claim 15, wherein the active region is formed by implanting P type impurity ions.

17. The method according to claim 15, wherein forming the junction includes implanting N type impurity ions into the active region.

18. The method according to claim 15, wherein the step of forming the gate pattern includes:
sequentially forming a gate oxide layer and a gate electrode layer over the semiconductor substrate; and
etching the gate electrode layer and the gate oxide layer by using a gate mask defining the gate pattern as an etch mask until the active region is exposed.

19. The method according to claim 18, wherein the gate electrode layer is formed by implanting N type impurity ions.

20. The method according to claim 18, wherein the gate electrode layer includes a polymer layer, a tungsten (W) layer, a titanium (Ti) layer, a tungsten nitride (WN) layer or a combination thereof.

21. The method according to claim 15, wherein the gate oxide layer overlapping with the active region is destroyed when a voltage is supplied.

22. The method according to claim 15, wherein each of the first and the second contact plugs includes a tungsten (W) layer, a titanium (Ti) layer, a titanium nitride (TiN) layer or a combination thereof.
